(19) United States
(12) Patent Application Publication
(10) Pub. No.: US 2004/0211987 A1
(43) Pub. Date: Oct. 28, 2004

(54) Field effect transistor (FET) reset device structure for photodiode image sensor

(75) Inventors: Ho-Ching Chien, Hsinchu (TW); Shou-Gwo Wuu, Hsin-Chu City (TW); Chien-Hsien Tseng, Hsinchu (TW); Dun-Nian Yuang, Taipei (TW); Jeng-Shyan Lin, Tainan (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/423,445

(22) Filed: Apr. 24, 2003

(51) Int. Cl. H01L 21/00

(52) U.S. Cl. 257/225; 438/48

(57) ABSTRACT

An image sensor optoelectronic product and a method for fabrication thereof comprise a photodiode region overlapping a source/drain region of the same polarity within a reset metal oxide semiconductor field effect transistor device. The image sensor optoelectronic product also comprises a bridging implant region of the same polarity as the photodiode region and the source/drain region. The bridging implant region overlaps the photodiode region, encompasses the source/drain region and extends laterally into the channel region of the reset metal oxide semiconductor field effect transistor device. The bridging implant region provides the image sensor optoelectronic product with attenuated leakage and attenuated white pixel cell susceptibility.

### BACKGROUND OF THE INVENTION

1. Field of the Invention

The present invention relates generally to optoelectronic microelectronic products. More particularly, the present invention relates to image sensor optoelectronic microelectronic products.

2. Description of the Related Art

Image sensor optoelectronic products, such as color filter image sensor array optoelectronic products, find use as imaging devices within consumer and industrial products such as photocopiers, document scanners and digital cameras. A generally common image sensor optoelectronic product is a complementary metal oxide semiconductor (CMOS) image sensor. Complementary metal oxide semiconductor image sensors employ for each pixel cell a photodiode in conjunction with a reset field effect transistor (FET) device, a source follower field effect transistor device and a row select field effect transistor device.

While complementary metal oxide semiconductor image sensor optoelectronic products are thus common in the art of optoelectronic product fabrication, they are nonetheless not entirely without problems. In that regard, it is often difficult to fabricate complementary metal oxide semiconductor image sensor optoelectronic products with attenuated electrical leakage and attenuated white pixel cell susceptibility.

It is thus desirable in the optoelectronic product fabrication art to fabricate complementary metal oxide semiconductor image sensor optoelectronic products with attenuated leakage and attenuated white pixel cell susceptibility.

It is towards the foregoing objects that the present invention is directed.

Various image sensor optoelectronic products having desirable properties, and methods for fabrication thereof, have been disclosed within the optoelectronic product fabrication art.

Included but not limiting among the image sensor optoelectronic products and methods for fabrication thereof are those disclosed within: (1) Merrill, in U.S. Pat. No. 5,614,744 (an image sensor optoelectronic product with attenuated leakage); (2) Netzer et al., in U.S. Pat. No. 6,177,293 (a method for fabricating an image sensor optoelectronic product with attenuated leakage); and (3) Kopley et al., in U.S. Pat. No. 6,350,664 (an additional method for fabricating an image sensor optoelectronic product with attenuated leakage).

The teachings of each of the foregoing references are incorporated herein fully by reference.

Desirable are additional image sensor optoelectronic products with attenuated leakage and attenuated white pixel cell susceptibility, as well as methods for fabrication thereof.

It is towards the foregoing objects that the present invention is directed.

### SUMMARY OF THE INVENTION

A first object of the invention is to provide an image sensor optoelectronic product, and a method for fabrication thereof.

A second object of the invention is to provide an image sensor optoelectronic product and method for fabrication thereof in accord with the first object of the invention, wherein the image sensor optoelectronic product is formed with attenuated leakage and attenuated white pixel cell susceptibility.

In accord with the objects of the invention, the invention provides an image sensor optoelectronic product and a method for fabricating the image sensor optoelectronic product.

In accord with the invention, the image sensor optoelectronic product comprises a semiconductor substrate having defined therein an active region comprising a first region of a first polarity laterally adjoining a photodiode region of a second polarity opposite the first polarity. The image sensor optoelectronic product also comprises a reset field effect transistor device formed within the first region and having a source/drain region of the second polarity overlapping the photodiode region. Finally, the image sensor optoelectronic product also comprises a bridging implant region of the second polarity formed overlapping the photodiode region and encompassing the source/drain region, and laterally extending into the channel region within the reset field effect transistor device.

The present invention provides an image sensor optoelectronic product and a method for fabrication thereof, wherein the image sensor optoelectronic product is formed with attenuated leakage and attenuated white pixel cell susceptibility.

The invention realizes the foregoing objects within the context of a complementary metal oxide semiconductor photodiode image sensor optoelectronic product having: (1) a photodiode region; and (2) a source/drain region within a reset field effect transistor device both of the same polarity and overlapping, by employing; (3) a bridging implant region also of the same polarity as the photodiode region and the source/drain region. Within the invention, the bridging implant region overlaps the photodiode region and encompasses the source/drain region, and extends laterally into the channel region of the reset field effect transistor device.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1, FIG. 2, FIG. 3, FIG. 4, FIG. 5 and FIG. 6 show a series of schematic cross-sectional diagrams illustrating the results of progressive stages of fabricating a complementary metal oxide semiconductor image sensor optoelectronic product in accord with the preferred embodiments of the invention.

### DESCRIPTION OF THE PREFERRED EMBODIMENTS

The present invention provides an image sensor optoelectronic product and a method for fabrication thereof, wherein the image sensor optoelectronic product is formed with attenuated leakage and attenuated white pixel cell susceptibility.

The invention realizes the foregoing object within the context of a complementary metal oxide semiconductor photodiode image sensor optoelectronic product having: (1) a photodiode region; and (2) a source/drain region within a reset field effect transistor device both of the same polarity and overlapping, by employing; (3) a bridging implant region also of the same polarity as the photodiode region and the source/drain region. Within the invention, the bridging implant region overlaps the photodiode region and encompasses the source/drain region, and extends laterally into the channel region of the reset field effect transistor device.

The present invention may be employed for forming image sensor optoelectronic products including but not limited to linear image sensor optoelectronic products and array image sensor optoelectronic products, of both the color filter variety and non-color filter variety.

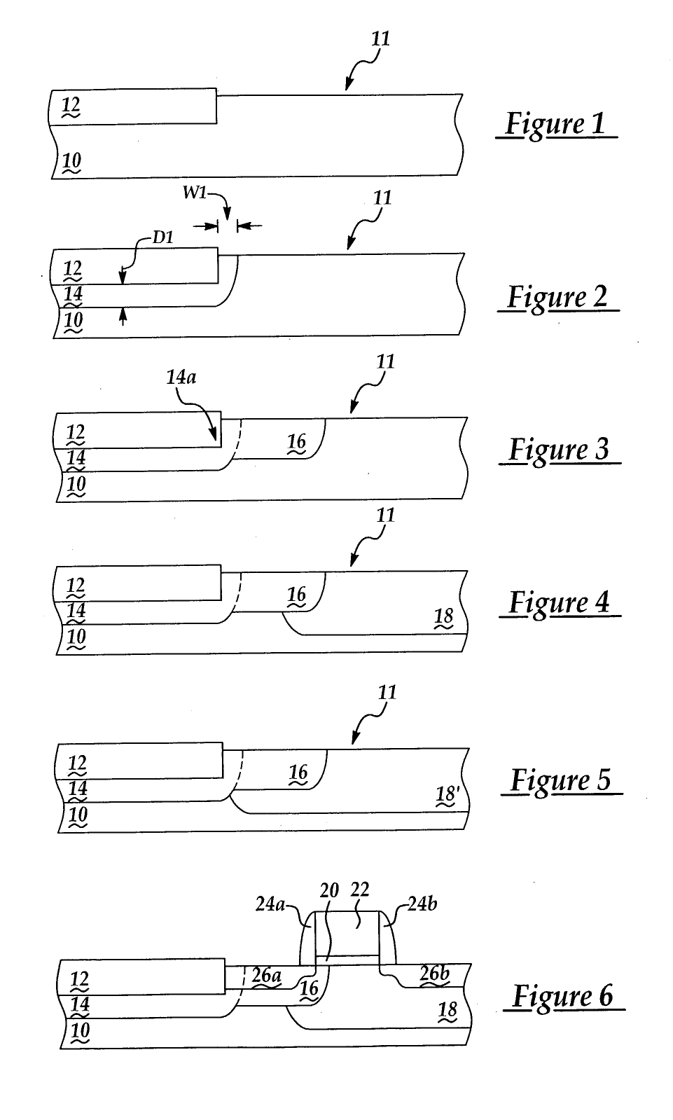

FIG. 1 to FIG. 6 show a series of schematic cross-sectional diagrams illustrating the results of progressive stages of fabricating an image sensor optoelectronic product in accord with the preferred embodiments of the invention.

FIG. 1 shows a schematic cross-sectional diagram of the image sensor optoelectronic product at an early stage in its fabrication in accord with the preferred embodiments of the invention.

FIG. 1 shows a semiconductor substrate 10 having formed therein an isolation region 12 which adjoins and defines an active region 11 of the semiconductor substrate 10.

Within the invention, the semiconductor substrate 10 may be provided as a semiconductor substrate formed of several semiconductor materials (i.e., silicon semiconductor materials and silicon-germanium alloy semiconductor materials), either dopant polarity, several dopant concentrations and various crystallographic orientations. Typically, the semiconductor substrate 10 is provided as a (100) silicon semiconductor substrate having a P− dopant concentration of from about 1E15 to about 1E16 dopant atoms per cubic centimeter.

Within the invention, the isolation region 12 is preferably formed as a shallow trench isolation region formed at least in part of a silicon oxide material, although other methods and materials may also be employed for forming isolation regions of other varieties. Typically, the isolation region 14 is formed to a thickness of from about 2000 to about 4000 angstroms and recessed at least in part within the semiconductor substrate 10.

FIG. 2 shows the results of further processing of the image sensor optoelectronic product of FIG. 1.

FIG. 2 shows a photodiode region 14 formed within the semiconductor substrate 10 such that a portion of the photodiode region 14 is beneath the isolation region 12 and a portion of the photodiode region 14 extends into the active region 11 of the semiconductor substrate 10. Thus, the active region comprises a first region of a first polarity adjoining the photodiode region 14.

Within the invention, the photodiode region 14 is of a second polarity opposite the first polarity of the semiconductor substrate 10. Typically, the photodiode region 14 is provided with an − dopant concentration of from about 1E16 to about 1E17 dopant atoms per cubic centimeter and a junction depth D1 beneath the isolation region 12 within the semiconductor substrate 10 of from about 2000 to about 30000 angstroms. Typically, a portion of the photodiode region 14 extends into the active region 11 of the semiconductor substrate 10 for a linewidth W1 from about 0.2 to about 0.5 microns.

FIG. 3 shows the results of further processing of the image array optoelectronic product of FIG. 2.

FIG. 3 shows the results of forming within the active region 11 of the semiconductor substrate 10 and overlapping the photodiode region 14, a bridging implant region 16.

Within the invention, the bridging implant region 16 is of the same second polarity as the photodiode region 14, and the bridging implant region 16 is formed of dimensions such that the bridging implant region 16: (1) will fully encompass (i.e., fully overlap and be of greater dimensions than) a source/drain region within a reset metal oxide semiconductor field effect transistor device to be formed within the active region 11 of the semiconductor substrate 10; (2) will extend laterally into a channel region within the reset metal oxide semiconductor field effect transistor device to be formed within the active region 11 of the semiconductor substrate 10; and (3) provides additional coverage to an adjacent interior corner 12a of the isolation region 12. Typically, the bridging implant region 16 is formed with a dopant concentration of from about 1E16 to about 1E18 dopant atoms per cubic centimeter, while employing an ion implant dose and an ion implant energy sufficient to provide the above enumerated dimensional conditions.

FIG. 4 shows a schematic cross-sectional diagram illustrating the results of further processing of the image array optoelectronic product of FIG. 3.

FIG. 4 shows the results of forming within the active region 11 of the semiconductor substrate 10 a doped well 18 of the same first polarity as the semiconductor substrate 10. The doped well 18 is formed with a dopant concentration of from about 1E16 to about 1E18 dopant atoms per cubic centimeter, such as not to compromise a somewhat higher concentration opposite polarity dopant within the bridging implant region 16.

FIG. 5 shows an alternative further processing of the image sensor optoelectronic product of FIG. 3.

FIG. 5 shows an alternative doped well region 18′ of increased lateral dimensions in comparison with the doped well region 18, such that the alternative doped well region 18′ abuts the photodiode region 14 in addition to the bridging implant region 16. Within the image sensor optoelectronic product of FIG. 4, the doped well 18 is intended to exclude one of the source/drain regions within the reset metal oxide semiconductor field effect transistor device to be formed within the active region 11 of the semiconductor substrate 10. In contrast, the doped well 18′ as illustrated within FIG. 5 is intended to encompass both source/drain regions within the reset metal oxide semiconductor field effect transistor device. Both the doped well 18 and the doped well 18′ are intended to include the channel region within the reset metal oxide semiconductor field effect transistor device.

FIG. 6 shows the results of further processing of the image sensor optoelectronic product of FIG. 4, although identical further processing may also be undertaken with respect to the image sensor optoelectronic product of FIG. 5.

FIG. 6 shows a reset metal oxide semiconductor field effect transistor device formed within and upon the active region 11 of the semiconductor substrate 10. The reset metal oxide semiconductor field effect transistor device comprises: (1) a gate dielectric layer 20 formed upon the active region 11 of the semiconductor substrate 10; (2) a gate electrode 22 formed aligned upon the gate dielectric layer 20; (3) a pair of spacer layers 24aand 24b formed adjoining a pair of opposite sidewalls of the gate dielectric layer 20 and the gate electrode 22; and (4) a pair of source/drain regions 26a and 26b formed into the active region 11 of the semiconductor substrate 10 at locations not covered by the gate electrode 22.

Within the invention, the gate dielectric layer 20, the gate electrode 22, the pair of spacer layers 24a and 24b and the pair of source/drain regions 26a and 26b may be formed employing methods and materials as are conventional in the microelectronic fabrication art. Typically, the gate dielectric layer 20 is formed at least in part of silicon oxide formed to a thickness of from about 30 to about 70 angstroms. Typically, the gate electrode 22 is formed of a doped polysilicon (having a dopant concentration of from about 1E20 to about 1E21 dopant atoms per cubic centimeter) or polycide (doped polysilicon/metal silicide stack) material formed to a thickness of from about 1000 to about 1500 angstroms. Typically, the pair of spacer layers 24a and 24b is formed of a silicon oxide or silicon nitride material. Typically, the pair of source/drain regions 26a and 26b is formed employing a two step ion implant method, with and without the spacers 24a and 24b. A heavier ion implant step within the two step ion implantation method provides the pair of source/drain regions 26a and 26b with a dopant concentration of from about 1E20 to about 1E21 dopant atoms per cubic centimeter.

Within the image sensor optoelectronic product of FIG. 6, the source/drain region 26a when formed of N polarity generally serves as a source region within the reset metal oxide semiconductor field effect transistor device. As is also illustrated within the schematic diagram of FIG. 6, the bridging implant region 16 fully encompasses the source/drain region 26a (with an additional depth within the active region 11 of the semiconductor substrate 10 of from about 2000 to about 10000 angstroms) and extends laterally into the channel region at the source side of the reset metal oxide semiconductor field effect transistor device, but not at the drain side of the reset metal oxide semiconductor field effect transistor device. The extension into the channel region is for a linewidth dimension of from about 0.1 to about 0.3 microns.

The invention provides a complementary metal oxide semiconductor photodiode image sensor optoelectronic product with attenuated leakage and attenuated white pixel cell susceptibility. While not wishing to be bound to any particular theory of operation of the invention, the invention presumably may realize the foregoing objects since the bridging implant region 16 is assumed to compensate for: (1) defects formed within the photodiode region 14 incident to processing of the image sensor optoelectronic product; and (2) defects formed within the active region 11 of the semiconductor substrate 10 when forming the gate electrode 22 and gate dielectric layer thereover, as well as the source/drain region 26a therein.

The preferred embodiments of the invention are illustrative of the invention rather than limiting of the invention. Revisions and modifications may be undertaken with respect to methods, materials, structures and dimensions in conjunction with an image sensor optoelectronic product in accord with the preferred embodiments of the invention, while still providing an optoelectronic product in accord with the present invention, further in accord with the accompanying claims.

What is claimed is:

1. An image sensor optoelectronic product comprising:
a semiconductor substrate having defined therein an active region comprising a first region of a first polarity laterally adjoining a photodiode region of a second polarity opposite the first polarity;
a reset field effect transistor device formed within the first region and having a source/drain region of the second polarity overlapping the photodiode region; and
a bridging implant region of the second polarity formed overlapping the photodiode region and encompassing the source/drain region, and extending laterally into the channel region within the reset field effect transistor device.

2. The image sensor optoelectronic product of claim 1 further comprising an isolation region recessed into the photodiode region such that a portion of the photodiode region is beneath the isolation region and a portion of the photodiode region extends into the active region.

3. The image sensor optoelectronic product of claim 1 further comprising a doped well of the first polarity formed into the active region of the semiconductor substrate and including the channel region within the reset field effect transistor device.

4. The image sensor optoelectronic product of claim 3 wherein the doped well is separated from the photodiode region.

5. The image sensor optoelectronic product of claim 3 wherein the doped well abuts the photodiode region.

6. The image sensor optoelectronic product of claim 1 wherein the bridging implant region extends laterally from about 0.1 to about 0.3 microns into the channel region.

7. The image array optoelectronic product of claim 1 wherein the first polarity is a P polarity and the second polarity is an N polarity.

8. A method for forming an image sensor optoelectronic product comprising:
providing a semiconductor substrate having defined therein an active region comprising a first region of a first polarity laterally adjoining a photodiode region of a second polarity opposite the first polarity;
forming within the semiconductor substrate a bridging implant region of the second polarity which overlaps the photodiode region and extends into the first region; and
forming within the first region a reset field effect transistor device, the reset field effect transistor device having a source/drain region of the second polarity overlapping the photodiode region, wherein the bridging implant region encompasses the source/drain region and extends laterally into a channel region within the reset field effect transistor device.

9. The method of claim 8 further comprising forming a doped well of the first polarity formed into the active region of the semiconductor substrate and including the channel region within the reset field effect transistor device.

10. The method of claim 9 wherein the doped well is separated from the photodiode region.

11. The method of claim 9 wherein the doped well abuts the photodiode region.

12. The method of claim 8 wherein the bridging implant region extends laterally from about 0.1 to about 0.3 microns into the channel region.

13. The method of claim 8 wherein the first polarity is a P polarity and the second polarity is an N polarity.

14. A method for forming an image sensor optoelectronic product comprising:
providing a semiconductor substrate of a first polarity having formed therein an isolation region which adjoins an active region of the semiconductor substrate;
forming into the semiconductor substrate a photodiode region of a second polarity opposite the first polarity such that a portion of the photodiode region is beneath the isolation region and a portion of the photodiode region extends into the active region;
forming within the semiconductor substrate a bridging implant region which overlaps the photodiode region and further extends into the active region of the semiconductor substrate; and
forming within the active region of the semiconductor substrate a reset field effect transistor device, the reset field effect transistor device having a source/drain region of the second polarity overlapping the photodiode region, wherein the bridging implant region encompasses the source/drain region and extends laterally into a channel region within the reset field effect transistor device.

15. The method of claim 14 further comprising forming a doped well of the first polarity into the active region of the semiconductor substrate and including the channel region within the reset field effect transistor device.

16. The method of claim 15 wherein the doped well is separated from the photodiode region.

17. The method of claim 15 wherein the doped well abuts the photodiode region.

18. The method of claim 14 wherein the photodiode region extends from about 0.2 to about 0.5 microns into the active region.

19. The method of claim 14 wherein the bridging implant region extends laterally from about 0.1 to about 0.3 microns into the channel region.

20. The method of claim 14 wherein the first polarity is a P polarity and the second polarity is an N polarity.
